(19) United States
(12) Patent Application Publication
(10) Pub. No.: US 2026/0349358 A1
(43) Pub. Date: Nov. 5, 2026

(54) MOVING DEVICE, EXPOSURE APPARATUS, METHOD FOR DRIVING MOBILE UNIT, EXPOSURE METHOD, AND DEVICE MANUFACTURING METHOD

(71) Applicant: NIKON CORPORATION, Tokyo (JP)

(72) Inventors: Nobuyuki SASAKURA, Yokohama-shi (JP); Akihiko TOMIE, Kamakura-shi (JP); Kazuyuki HIRACHI, Kamakura-shi (JP); Yosuke HAYASHIDA, Kawasaki-shi (JP)

(73) Assignee: NIKON CORPORATION, Tokyo (JP)

(21) Appl. No.: 19/711,942

(22) Filed: Jun. 18, 2026

Related U.S. Application Data
(63) Continuation of application No. PCT/JP2024/043468, filed on Dec. 9, 2024.

(30) Foreign Application Priority Data
Dec. 19, 2023 (JP) 2023-213947

(51) Int. Cl. G03F 7/00; G01B 11/14; G03F 7/20

(52) U.S. Cl. CPC G03F 7/70725; G01B 11/14; G03F 7/20

(57) ABSTRACT

An exposure apparatus has a stage moving device (7). The stage moving device (7) includes a first mobile unit (32) extending in an X-axis direction and moving in a Y-axis direction, a second mobile unit (34) moving in the Y-axis direction, a first measurement system (36), and a second measurement system (37). The first measurement system (36) measures a position of the second mobile unit (34) in the X-axis direction by using a first head (45) provided on the second mobile unit (34) and a scale (41) extending in the X-axis direction and provided on the first mobile unit (32) so as to face the first head (45). The second measurement system (37) acquires information relating to a spacing in the Y-axis direction between the first mobile unit (32) and the second mobile unit

### CROSS-REFERENCE TO RELATED APPLICATIONS

This is a Continuation Application of International Application No. PCT/JP2024/043468, filed Dec. 9, 2024, which claims priority to Japanese Application No. JP 2023-213947, filed Dec. 19, 2023. The contents of the aforementioned applications are incorporated herein by reference.

### BACKGROUND

### Field of the Invention

The present invention relates to a moving device, an exposure apparatus, a method for driving a mobile unit, an exposure method, and a device manufacturing method.

Priority is claimed on Japanese Patent Application No. 2023-213947, filed Dec. 19, 2023, the content of which is incorporated herein by reference.

### Description of Related Art

Conventionally, in a lithography process for manufacturing electronic devices (micro-devices) such as a liquid-crystal display element or a semiconductor element (an integrated circuit, etc.), an exposure apparatus that transfers a predetermined pattern of a mask (photomask) or a reticle (hereinafter, collectively referred to as a “mask”) onto a substrate by exposing a photosensitive glass plate or wafer (hereinafter, collectively referred to as a “substrate”) with illumination light (energy beam) through a projection optical system is used.

As this type of exposure apparatus, since it is necessary to control the position of the substrate with respect to the projection optical system with high precision, an apparatus using a linear encoder system as a position measurement system for a stage on which the substrate is loaded is known (for example, see Patent Document 1).

### CITATION LIST

### Patent Document

Patent Document 1: U.S. Patent Application Publication No. 2010/0266961

### SUMMARY OF INVENTION

Here, in a case in which position information of the substrate is obtained using an optical interferometer system, an optical path length of a laser beam to a bar mirror becomes long, and the influence of so-called air fluctuation cannot be ignored.

According to a first aspect of the present invention, there is provided a moving device including: a first mobile unit extending in a first direction and moving in a second direction intersecting the first direction; a second mobile unit moving in the second direction; a first measurement system measuring a position of the second mobile unit in the first direction by using a first head provided on one of the first mobile unit and the second mobile unit and a scale extending in the first direction and provided on the other of the first mobile unit and the second mobile unit so as to face the first head; and a second measurement system acquiring information relating to a spacing between the first mobile unit and the second mobile unit.

According to a second aspect of the present invention, there is provided a moving device including: a first mobile unit extending in a first direction and moving in a second direction intersecting the first direction; a second mobile unit moving in the second direction; a first measurement system measuring a position of the second mobile unit in the first direction by using a first head provided on one of the first mobile unit and the second mobile unit and a scale extending in the first direction and provided on the other of the first mobile unit and the second mobile unit so as to face the first head; a second measurement system acquiring information relating to a positional relation between the first mobile unit and the second mobile unit in the second direction; and a third measurement system measuring a position of the first mobile unit in the second direction, in which positions of the second mobile unit in the first direction and the second direction are controlled on the basis of measurement results acquired by the first measurement system, the second measurement system, and the third measurement system.

According to a third aspect of the present invention, a method for driving a mobile unit is a method for driving a mobile unit that moves a first mobile unit extending in a first direction and moving in a second direction intersecting the first direction and a second mobile unit moving in the second direction, the method including: measuring a position of the second mobile unit in the first direction by using a first head provided on one of the first mobile unit and the second mobile unit and a scale extending in the first direction and provided on the other of the first mobile unit and the second mobile unit so as to face the first head; acquiring information relating to a spacing between the first mobile unit and the second mobile unit; and driving the first mobile unit and the second mobile unit on the basis of a measurement result relating to the second mobile unit and the information relating to the spacing.

According to a fourth aspect of the present invention, a method for driving a mobile unit is a method for driving a mobile unit that moves a first mobile unit extending in a first direction and moving in a second direction intersecting the first direction and a second mobile unit moving in the second direction, the method including: measuring a position of the second mobile unit in the first direction by using a first head provided on one of the first mobile unit and the second mobile unit and a scale extending in the first direction and provided on the other of the first mobile unit and the second mobile unit so as to face the first head; acquiring information relating to a positional relation between the first mobile unit and the second mobile unit in the second direction; measuring a position of the first mobile unit in the second direction; and controlling positions of the second mobile unit in the first direction and the second direction on the basis of the measured position of the second mobile unit in the first direction, the acquired information relating to the positional relation between the first mobile unit and the second mobile unit, and the measured position of the first mobile unit in the second direction.

According to a fifth aspect of the present invention, there is provided an exposure method of exposing an object using an exposure apparatus including a first mobile unit extending in a first direction and moving in a second direction intersecting the first direction, a second mobile unit moving in the second direction, the object held by the second mobile unit, and an optical system that emits light to the object, the method including: measuring a position of the second mobile unit in the first direction by using a first head provided on one of the first mobile unit and the second mobile unit and a scale extending in the first direction and provided on the other of the first mobile unit and the second mobile unit so as to face the first head; acquiring information relating to a spacing between the first mobile unit and the second mobile unit; controlling movement of the first mobile unit and the second mobile unit on the basis of a measurement result relating to the second mobile unit and the information relating to the spacing; and exposing the object with the light from the optical system while moving the second mobile unit holding the object in the first direction.

### BRIEF DESCRIPTION OF DRAWINGS

FIG. 1 A diagram schematically showing a configuration of an exposure apparatus according to a first embodiment.

FIG. 2 An external perspective view schematically showing a configuration of the exposure apparatus according to the first embodiment.

FIG. 3 A diagram schematically showing a configuration of an illumination optical apparatus according to the first embodiment.

FIG. 4 A front view schematically showing a configuration of a stage moving device according to the first embodiment.

FIG. 5 A plan view schematically showing a configuration of the stage moving device according to the first embodiment.

FIG. 6 A front view schematically showing a configuration of the stage moving device according to the first embodiment after movement.

FIG. 7 An external perspective view showing a part of the exposure apparatus according to the first embodiment.

FIG. 8 An external perspective view of a part of the exposure apparatus according to the first embodiment viewed diagonally from above.

FIG. 9 A plan view schematically showing a configuration of a stage moving device according to a second embodiment.

FIG. 10 A front view schematically showing a configuration of the stage moving device according to the second embodiment.

FIG. 11 A plan view schematically showing a configuration of a plurality of encoder measurement systems of the stage moving device according to the second embodiment.

FIG. 12 A plan view schematically showing a configuration of a stage moving device according to a third embodiment.

FIG. 13 A front view schematically showing a configuration of the stage moving device according to the third embodiment.

FIG. 14 A plan view schematically showing a configuration of a stage moving device according to a fourth embodiment.

FIG. 15 A front view schematically showing a configuration of the stage moving device according to the fourth embodiment.

FIG. 16 A plan view schematically showing a configuration of a stage moving device according to a fifth embodiment.

FIG. 17 A front view schematically showing a configuration of the stage moving device according to the fifth embodiment.

FIG. 18 A plan view schematically showing a configuration of a stage moving device according to a sixth embodiment.

FIG. 19 A front view schematically showing a configuration of the stage moving device according to the sixth embodiment.

### DESCRIPTION OF EMBODIMENTS

Hereinafter, embodiments of the present invention will be described with reference to the drawings. The following detailed description of the present invention is merely exemplary and is not limiting. Throughout the drawings and the following detailed description, the same or similar reference numerals are used.

### First Embodiment

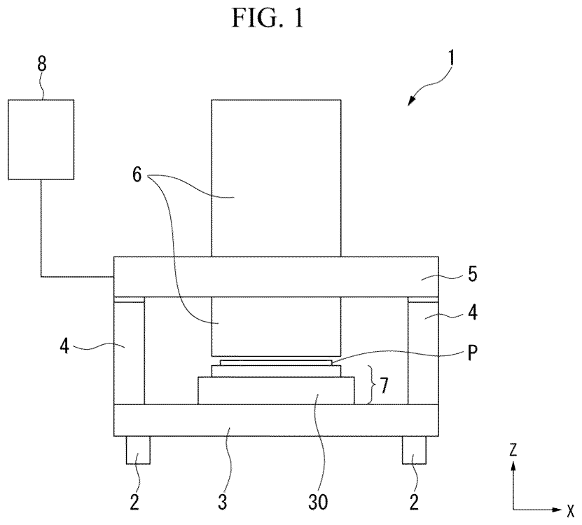

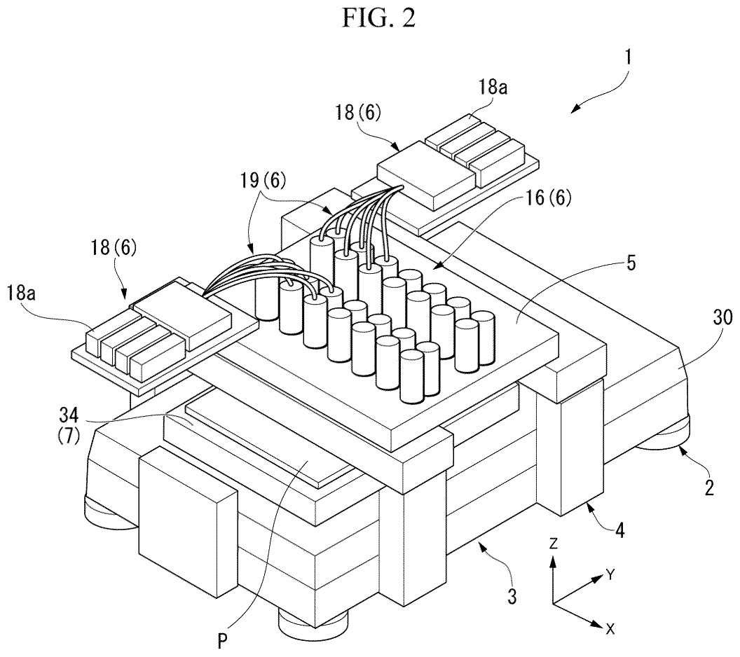

FIG. 1 is a diagram schematically showing the configuration of an exposure apparatus 1 according to a first embodiment. FIG. 2 is an external perspective view schematically showing the configuration of the exposure apparatus 1 according to the first embodiment.

As shown in FIGS. 1 and 2, the exposure apparatus 1 is an apparatus that emits modulated light to an exposure target object P. In a specific embodiment, the exposure apparatus 1 is a step-and-scan type projection exposure apparatus, a so-called scanner that uses a rectangular (square) glass substrate used for a liquid-crystal display device (flat-panel display) or the like as an exposure target object. The glass substrate P, which is the exposure target object, has at least a length of one side or a diagonal length of 500 mm or more and may be a substrate for a flat-panel display. The exposure target object P (for example, a substrate for a flat-panel display) exposed by the exposure apparatus 1 is developed into a product.

The exposure apparatus 1 includes an anti-vibration table 2, a pedestal unit 3, a main column 4, an optical surface plate 5, an illumination optical apparatus 6 (optical system), a stage moving device 7 (moving device), and a control unit 8.

In the following description, a three-dimensional orthogonal coordinate system in which a direction parallel to an optical axis direction of light emitted from the illumination optical apparatus 6 toward the exposure target object P is defined as a Z-axis direction (third direction), a direction of a predetermined plane orthogonal to the Z-axis is defined as an X-axis direction (first direction), and a direction orthogonal to both the Z-axis and the X-axis is defined as a Y-axis direction (second direction) will be used as necessary. In the present embodiment, a direction in which the exposure target object P (glass substrate) is relatively scanned with respect to a projection module 17 of the illumination optical apparatus 6 at the time of an exposure operation is set as the X-axis direction.

The anti-vibration table 2 is installed on the ground (ground contact surface).

The pedestal unit 3 is a base of the exposure apparatus 1 and is installed on the anti-vibration table 2. The pedestal unit 3 supports a stage (second mobile unit 34) of the stage moving device 7 on which the exposure target object P is placed so as to be movable in the X-axis direction and the Y-axis direction.

The stage moving device 7 supports an exposure target object P and is for positioning the exposure target object P with high precision with respect to a plurality of partial images of a circuit pattern projected through the projection module 17 of the illumination optical apparatus 6 during scanning exposure. The stage moving device 7 drives the exposure target object P in 6 degree-of-freedom directions (the above-described X-axis, Y-axis, and Z-axis directions and θx, θy, and θz directions that are rotational directions with respect to the respective axes). The second mobile unit 34, which is a movable portion of the stage moving device 7, is moved in the X-axis direction when scanning exposure is performed and is moved in the Y-axis direction when an exposure target region on the exposure target object P is changed. A plurality of exposure target regions are formed on the exposure target object P. The exposure apparatus 1 can respectively expose a plurality of exposure target regions on one exposure target object P. As the stage moving device 7, a stage device having a so-called coarse/fine movement configuration including a gantry-type two-dimensional coarse movement stage and a fine movement stage finely driven with respect to this two-dimensional coarse movement stage can be used. In this case, the exposure target object P can be moved in 3 degree-of-freedom directions within a horizontal plane by the coarse movement stage, and the exposure target object P can be finely moved in 6 degree-of-freedom directions by the fine movement stage. Details of the stage moving device 7 will be described below.

The main column 4 supports the optical surface plate 5 at an upper part (a positive direction of the Z-axis) of the stage moving device 7. The optical surface plate 5 supports the illumination optical apparatus 6.

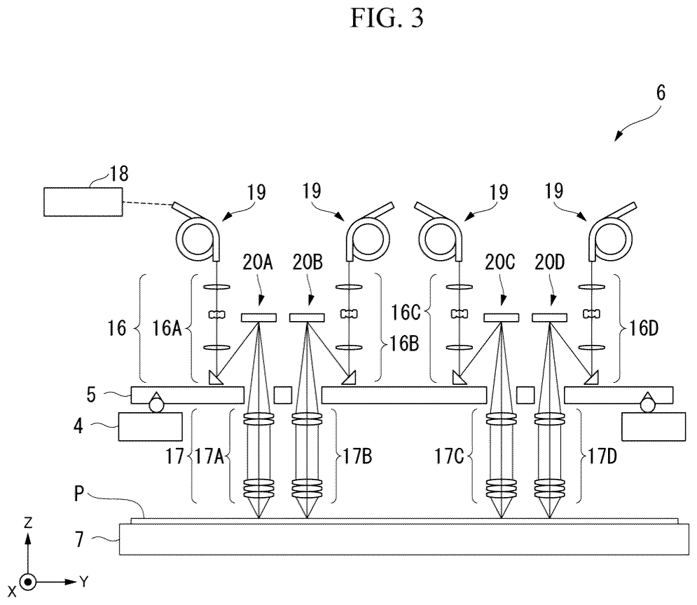

FIG. 3 is a diagram schematically showing the configuration of the illumination optical apparatus 6 according to the first embodiment.

As shown in FIG. 3, the illumination optical apparatus 6 includes an illumination module 16, a projection module 17 (projection optical system), a light source unit 18, and a light modulation unit 20.

The illumination module 16 is arranged on an upper portion of the optical surface plate 5 and is connected to the light source unit 18 through an optical fiber 19. In an example of the present embodiment, the illumination module 16 includes a first illumination module 16A, a second illumination module 16B, a third illumination module 16C, and a fourth illumination module 16D. In the following description, in a case in which the first illumination module 16A to the fourth illumination module 16D do not need to be distinguished from each other, they are collectively referred to as the illumination module 16.

The first illumination module 16A to the fourth illumination module 16D respectively guide light emitted from the light source unit 18 through the optical fiber 19 to a first light modulation unit 20A, a second light modulation unit 20B, a third light modulation unit 20C, and a fourth light modulation unit 20D. The illumination module 16 illuminates the light modulation unit 20. The first illumination module 16A and the first light modulation unit 20A are arranged to be aligned in a scanning direction. The second illumination module 16B and the second light modulation unit 20B are arranged to be aligned in the scanning direction. The third illumination module 16C and the third light modulation unit 20C are arranged to be aligned in the scanning direction. The fourth illumination module 16D and the fourth light modulation unit 20D are arranged to be aligned in the scanning direction.

The light modulation unit 20 is controlled on the basis of a circuit pattern to be transferred onto the exposure target object P and modulates the illumination light from the illumination module 16. The modulated light modulated by the light modulation unit 20 is guided to the projection module 17. The first light modulation unit 20A to the fourth light modulation unit 20D are arranged at positions different from each other on an XY plane. In the following description, in a case in which the first light modulation unit 20A to the fourth light modulation unit 20D do not need to be distinguished from each other, they are collectively referred to as the light modulation unit 20.

The projection module 17 is arranged below the optical surface plate 5 and emits the modulated light modulated by the light modulation unit 20 onto the exposure target object P placed on the stage moving device 7. The projection module 17 forms an image of the light modulated by the light modulation unit 20 on the exposure target object P and exposes the exposure target object P. In other words, the projection module 17 projects a pattern on the light modulation unit 20 onto the exposure target object P. A plane including an optical axis of the illumination light illuminating the light modulation unit 20 and an optical axis of the projection module 17 is provided in parallel to the scanning direction (X-axis direction). In an example of the present embodiment, the projection module 17 includes a first projection module 17A to a fourth projection module 17D corresponding to the first illumination module 16A to the fourth illumination module 16D and the first light modulation unit 20A to the fourth light modulation unit 20D described above. In the following description, in a case in which the first projection module 17A to the fourth projection module 17D do not need to be distinguished from each other, they are collectively referred to as the projection module 17.

A unit composed of the first illumination module 16A, the first light modulation unit 20A, and the first projection module 17A is referred to as a first exposure module. Similarly, a unit composed of the second illumination module 16B, the second light modulation unit 20B, and the second projection module 17B is referred to as a second exposure module. The exposure modules are provided at mutually-different positions on the XY plane and can expose a pattern onto mutually-different positions on the exposure target object P placed on a stage 14. The stage 14 can perform scanning exposure on the entire surface of the exposure target object P or the entire surface of the exposure target region by relatively moving in the X-axis direction that is the scanning direction with respect to the exposure module.

The illumination module 16 is also referred to as an illumination system. The illumination module 16 (illumination system) illuminates a spatial light modulation element of the light modulation unit 20.

The projection module 17 is also referred to as a projection unit. The projection module 17 (projection unit) may be an equal-magnification system that projects the image of the pattern on the light modulation unit 20 at equal magnification or may be an enlargement system or a reduction system. Furthermore, the projection module 17 is preferably composed of one or two kinds of glass materials (particularly quartz or fluorite).

As shown in FIG. 2, a pair of light source units 18 are provided. As the light source units 18, a light source unit using a highly coherent laser as a light source, a light source unit using a light source such as a semiconductor laser type UV-LD, a light source unit using a lens relay type retarder, and the like can be adopted. Examples of the light source 18a included in the light source unit 18 include a lamp, a laser diode, and the like that emit light with a wavelength of 405 nm or 365 nm.

In addition to the units described above, the exposure apparatus 1 includes an autofocus (AF) unit (not shown) that measures the position of the exposure target object P on the stage moving device 7 in the Z-axis direction. Furthermore, the exposure apparatus 1 may include an alignment unit (not shown) that measures a relative position of each pattern when overlapping and exposing another pattern on a pattern already exposed on the exposure target object P. The AF unit and the alignment unit may have a TTL (through-the-lens) configuration that performs measurement through the projection module 17.

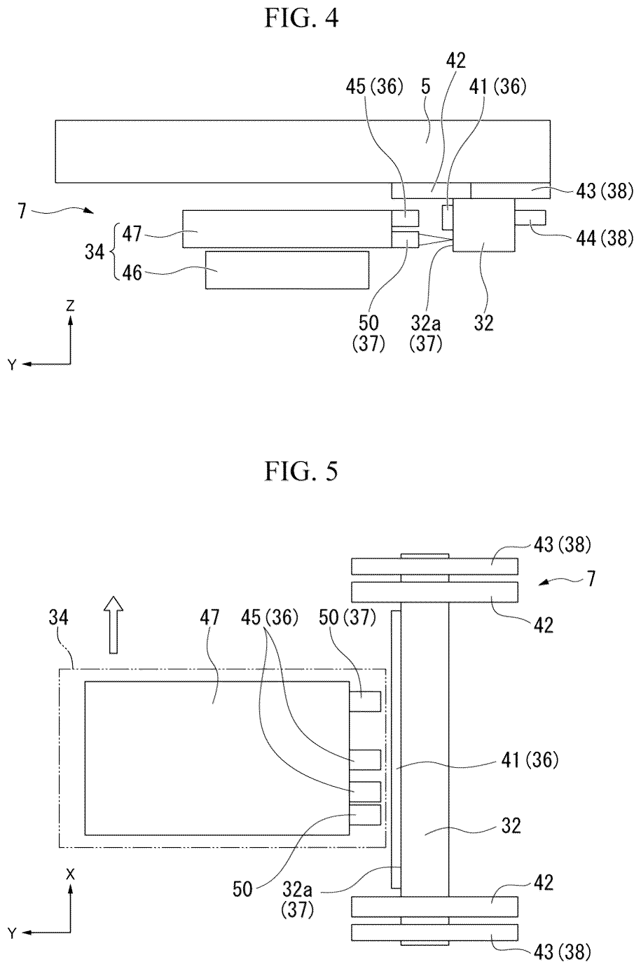

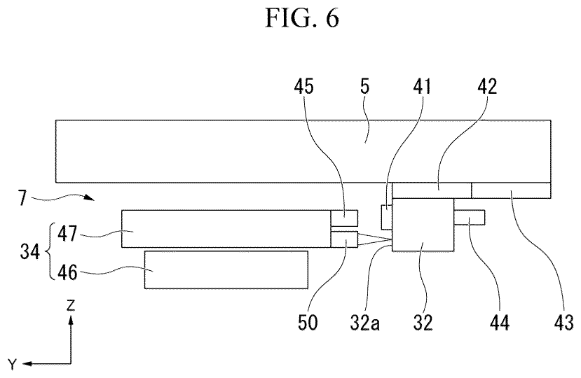

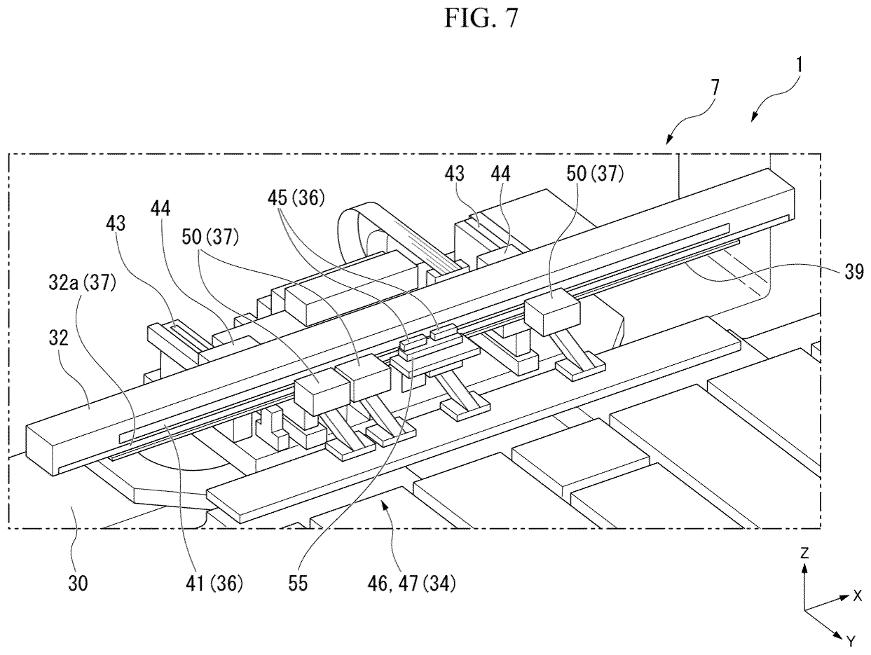

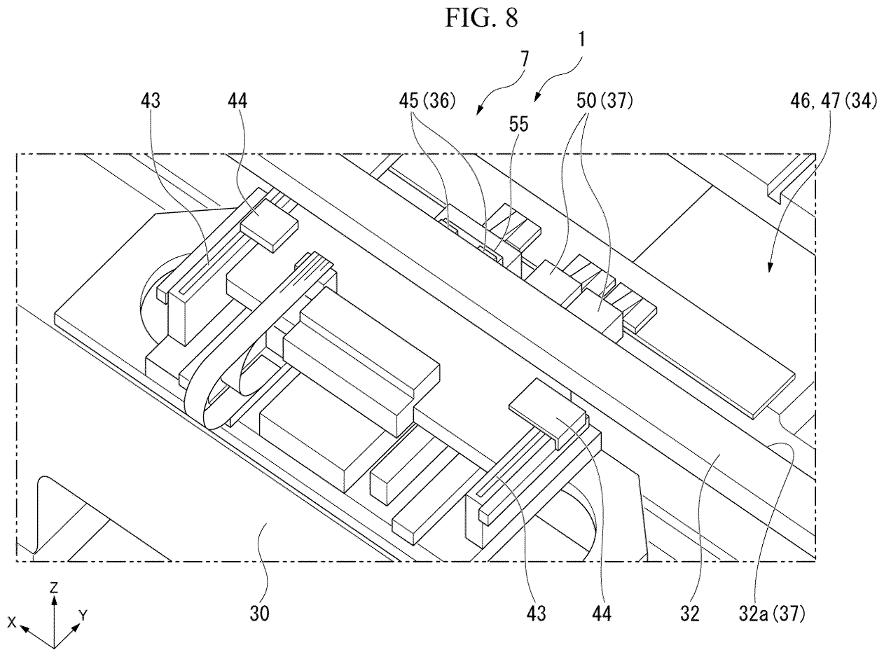

FIG. 4 is a front view schematically showing the configuration of the stage moving device 7 according to the first embodiment. FIG. 5 is a plan view schematically showing the configuration of the stage moving device 7 according to the first embodiment. FIG. 6 is a front view schematically showing the configuration of the stage moving device 7 according to the first embodiment after movement. FIG. 6 shows a state after a first mobile unit 32 and the second mobile unit 34 have moved in the Y-axis direction (+Y direction in the figure) from the state shown in FIG. 4. FIG. 7 is an external perspective view showing a part of the exposure apparatus 1 according to the first embodiment. FIG. 7 is a perspective view mainly showing the external view of the first mobile unit 32. FIG. 8 is an external perspective view of a part of the exposure apparatus 1 according to the first embodiment viewed diagonally from above. FIG. 8 is a perspective view mainly showing the first mobile unit 32 viewed diagonally from above. In FIGS. 4 to 8, the illustration of the exposure target object P is omitted.

As shown in FIGS. 2, 4, and 5, the stage moving device 7 is provided below the optical surface plate 5 and on an upper part of the pedestal unit 3. The stage moving device 7 has a base member 30 (see FIGS. 1 and 2) attached to the pedestal unit 3, a first mobile unit 32 and a second mobile unit 34 configured to be movable with respect to the base member 30, and a first measurement system 36, a second measurement system 37, and a third measurement system 38.

As shown in FIG. 2, the base member 30 is fixed to the upper part of the pedestal unit 3. In other words, the base member 30 is provided immovably with respect to the pedestal unit 3. The base member 30, for example, may be integrally formed with the pedestal unit 3.

As shown in FIGS. 4, 5, and 7, the first mobile unit 32 is, for example, a long member for installing an encoder. The first mobile unit 32 is, for example, a moving mirror having a reflection surface 32a on at least a part thereof. The first mobile unit 32 extends along the X-axis direction and moves along the Y-axis direction with respect to the base member 30. Since the base member 30 and the optical surface plate 5 are fixed to each other, “moves with respect to the base member 30” may be synonymous with “moves with respect to the optical surface plate 5”. In FIGS. 4 and 6, for the sake of explanation, a state in which the first mobile unit 32 is movably attached to the optical surface plate 5 is illustrated as an example.

The first mobile unit 32 is attached to the base member 30 through a Y guide 42. A pair of Y guides 42 are arranged on the base member 30. The Y guide 42 extends in the Y-axis direction and is formed in a rectangular shape in an XZ cross section. The Y guide 42 is fixed to the base member 30. The Y guide 42 and the base member 30 may be integrally formed. The pair of Y guides 42 are arranged in parallel at a predetermined spacing in the X-axis direction. The pair of Y guides 42 have a linear guide mechanism and a drive motor that are not shown. By driving the linear guide mechanism and the drive motor using a signal from the control unit 8, the first mobile unit 32 is movable in the Y-axis direction on the base member 30.

As shown in FIGS. 4 and 6, the first mobile unit 32 moves in steps in the Y-axis direction following the step movement of the second mobile unit 34 in the Y-axis direction on which an exposure target object P to be described below is placed. In accordance with this, control is performed such that a distance along the Y-axis direction between the first mobile unit 32 and the second mobile unit 34 becomes constant. While the second mobile unit 34 is being scanned in the X direction, the first mobile unit 32 is controlled to remain stationary.

A Y encoder scale 43 (second measurement member) extending along the Y-axis direction is attached to the base member 30. The Y encoder scale 43 is a band-shaped member extending along the Y-axis direction and has on its upper surface (the surface facing the +Z direction) a reflective one-dimensional diffraction grating of which a periodic direction is the Y-axis direction. Furthermore, as shown in FIG. 4, the first mobile unit 32 is provided with a Y encoder head 44 so as to face this Y encoder scale 43 in the Z direction. The Y encoder head 44 emits a measurement beam to the corresponding Y encoder scale 43 and receives light (here, diffracted light) from the Y encoder scale 43. The position of the first member in the Y-axis direction is measured by the Y encoder scale 43 and the Y encoder head 44. A member to which the Y encoder scale 43 is attached is preferably formed of a material that is unlikely to undergo thermal deformation such as, for example, ceramics. In addition, the Y encoder scale 43 may have a reflective two-dimensional diffraction grating of which periodic directions are two axial directions orthogonal to each other (for example, the Y-axis direction and the X-axis direction). In this case, the first mobile unit 32 may also be movable in the X-axis direction with respect to the Y guide 42. Alternatively, an X moving stage that is not shown may be further provided between the Y guide 42 and the base member 30, and the Y guide 42 may be attached onto this X moving stage. In other words, the first mobile unit 32 may be configured to be movable in two axes including the X-axis and the Y-axis by the X moving stage moving in the X-axis direction with respect to the base member 30 and the Y guide 42 moving in the Y-axis direction with respect to the X moving stage.

The first mobile unit 32 extends along the X-axis direction and is formed in a rectangular shape in a YZ cross section. The first mobile unit 32 has a reflection surface 32a formed on at least a surface corresponding to a side on which the second mobile unit 34, which will be described below, is provided. In the present embodiment, the first mobile unit 32 is formed such that all four surfaces facing both sides in the Y direction and both sides in the Z direction become reflection surfaces 32a. The first mobile unit 32 has the reflection surfaces 32a formed by performing metal vapor deposition on the surface of a rod-shaped member formed in a rectangular cross-sectional shape. The first mobile unit 32 is preferably formed of a material that is unlikely to undergo thermal deformation such as, for example, ceramics. Of the four surfaces of the first mobile unit 32 having the reflection surfaces 32a, a surface corresponding to a side on which the second mobile unit 34 to be described below is provided (a surface facing the +Y-axis direction in the present embodiment) is provided with an X encoder scale 41 (scale) extending along the X-axis direction. In other words, the X encoder scale 41 and the reflection surface 32a are provided on the same side (the same surface facing the same direction) of the first mobile unit 32. The X encoder scale 41 is attached to the surface of the first mobile unit 32, for example, using an adhesive or the like. Similar to the Y encoder scale 43 described above, the X encoder scale 41 has, for example, a one-dimensional diffraction grating of which a periodic direction is the X-axis direction.

The second mobile unit 34 is, for example, a precision stage. The second mobile unit 34 moves along the X-axis direction and the Y-axis direction with respect to the base member 30. The second mobile unit 34 has a plate table 46 provided to be movable with respect to the base member 30 and a plate holder 47 that is fixed on the plate table 46 and holds an exposure target object P. A coarse movement XY stage (not shown) is provided between the plate table 46 and the base member 30. Similar to the first mobile unit 32, the second mobile unit 34 has a linear guide mechanism and a drive motor that are not shown and is configured to be movable in the X-axis and Y-axis directions on the base member 30 by driving the linear guide mechanism and the drive motor using a signal from the control unit 8. The second mobile unit 34 is controlled to be scanned along the X-axis direction when an exposure operation is performed for the exposure target object P and to perform a step movement in the Y-axis direction when the exposure target region is changed.

The plate holder 47 of the second mobile unit 34 is provided with an X encoder head 45 (first head). As shown in FIGS. 5 and 7, a plurality (two in the present embodiment) of X encoder heads 45 are provided to be aligned in the X-axis direction. A pair of X encoder heads 45 face the X encoder scale 41 of the first mobile unit 32 in the Y-axis direction. The X encoder head 45 emits a measurement beam to the corresponding X encoder scale 41 and receives light (here, diffracted light) from the X encoder scale 41. The light from the X encoder scale 41 is supplied to a detector that is not shown, and an output of the detector is supplied to the control unit 8 (see FIG. 1). The “encoder head” in the present specification only needs to have a portion which emits a measurement beam to the diffraction grating and into which the light from the diffraction grating enters, and the encoder head itself shown in each drawing does not need to have a light source, a detector, and the like.

The plate table 46 and the plate holder 47 are formed of a member having a smaller coefficient of thermal expansion than the X encoder scale 41 provided on the first mobile unit 32. By providing the X encoder head 45 on a member having a small coefficient of thermal expansion in this way, the relative position of the second mobile unit 34 with respect to the first mobile unit 32 can be precisely measured. In addition, by providing the pair of X encoder heads 45 aligned in the X-axis direction, the absolute position of the second mobile unit 34 can be measured. By reading one X encoder scale 41 using the pair of X encoder heads 45, which are aligned in the X-axis direction, mounted on a base 55 (table) having a small coefficient of thermal expansion, absolute value correction can be performed in real time. For example, the base 55 may be composed of a material having a smaller coefficient of thermal expansion than the X encoder scale 41.

As shown in FIGS. 4 to 7, the plate holder 47 of the second mobile unit 34 is further provided with an interferometer head 50 (second head). A plurality (two in the present embodiment) of interferometer heads 50 are provided to be aligned in the X-axis direction. In the present embodiment, a pair of X encoder heads 45 are provided between a pair of interferometer heads 50 in the X-axis direction. The pair of interferometer heads 50 are provided so as to respectively face the reflection surface 32a of the first mobile unit 32 in the Y-axis direction. A distance between the interferometer head 50 and the reflection surface 32a is larger than a distance between the X encoder head 45 and the X encoder scale 41.

In the above-described embodiment, although the configuration in which the X encoder head 45 and the interferometer head 50 are provided on the plate holder 47 has been described as an example, the configuration is not limited thereto. For example, the X encoder head 45 and the interferometer head 50 may be provided on the plate table 46. Alternatively, they may be provided on another member of the second mobile unit 34 that moves integrally with the plate holder 47 and the plate table 46.

The first measurement system 36 includes the X encoder scale 41 provided on the first mobile unit 32 described above and the X encoder head 45 provided on the second mobile unit 34. The first measurement system 36 measures the position of the second mobile unit 34 in the X-axis direction by using the X encoder head 45 provided on the second mobile unit 34 and the X encoder scale 41 provided on the first mobile unit 32 so as to face the X encoder head 45. A measurement result acquired by the first measurement system 36 is transmitted to the control unit 8.

The second measurement system 37 is an optical interferometer system including the reflection surface 32a provided on the first mobile unit 32 described above and the interferometer head 50 provided on the second mobile unit 34. The second measurement system 37 acquires information relating to a positional relation between the first mobile unit 32 and the second mobile unit 34 in the Y-axis direction by using the reflection surface 32a of the first mobile unit 32 and the interferometer head 50 of the second mobile unit 34. More specifically, the second measurement system 37 acquires information relating to a spacing in the Y-axis direction between the first mobile unit 32 and the second mobile unit 34. The information relating to the spacing is, for example, an amount of change in the spacing when the positional relation between the first mobile unit 32 and the second mobile unit 34 changes. The “spacing in the Y-axis direction” may be synonymous with “a distance along the Y-axis direction”. Here, since a pair of interferometer heads 50 are provided, the second measurement system 37 can acquire information relating to the spacing in the Y-axis direction between the first mobile unit 32 and the second mobile unit 34 at a plurality of positions in the X-axis direction. Thus, the second measurement system 37 measures the position of the second mobile unit 34 with respect to the first mobile unit 32 in the Y-axis direction and the θz direction. The information relating to the spacing acquired by the second measurement system 37 is transmitted to the control unit 8.

The distance along the Y-axis direction between the X encoder head 45 of the first measurement system 36 and the X encoder scale 41 is significantly smaller than the distance along the Y-axis direction between the interferometer head 50 of the second measurement system 37 (that is, the optical interferometer system) and the reflection surface 32a. For this reason, in the first measurement system 36 using the linear encoder system, the influence of air fluctuation is smaller than that in the second measurement system 37 using the optical interferometer system, and the position of the exposure target object P can be controlled with high precision, whereby the exposure precision can be improved.

The third measurement system 38 includes the Y encoder scale 43 provided on the base member 30 described above and the Y encoder head 44 provided on the first mobile unit 32. The third measurement system 38 measures the position of the first mobile unit 32 in the Y-axis direction with respect to the base member 30 by using the Y encoder scale 43 provided on the base member 30 and the Y encoder head 44 provided on the first mobile unit 32 so as to face the Y encoder scale 43. A measurement result acquired by the third measurement system 38 is transmitted to the control unit 8.

The control unit 8 (see FIG. 1) includes a so-called microcomputer (or a workstation) formed using a central processing unit (CPU), a read-only memory (ROM), a random access memory (RAM), and the like and integrally controls the entire exposure apparatus 1. The control unit 8 may be provided integrally with the exposure apparatus 1, or may be provided as an external device separate from the exposure apparatus 1 and communicably connected to the exposure apparatus 1 in a wired or wireless manner.

In the exposure apparatus 1, the control unit 8 controls the positions of at least the first mobile unit 32 and the second mobile unit 34. For example, at the time of performing an exposure operation or the like, the positions of the first mobile unit 32 and the second mobile unit 34 are managed by the control unit 8 on the basis of measured values of the measurement systems (including the first measurement system 36 and the second measurement system 37). The positions of the first mobile unit 32 and the second mobile unit 34 may be managed and controlled on the basis of the measured values of the measurement systems also at the time of performing a wafer alignment operation.

In the present embodiment, the control unit 8 acquires the measurement result of the first measurement system 36, the information obtained by the second measurement system 37, and the measurement result of the third measurement system 38. The control unit 8 controls a spacing in the Y-axis direction between the first mobile unit 32 and the second mobile unit 34 on the basis of the measurement result of the second measurement system 37. More specifically, the control unit 8 controls the position of the second mobile unit 34 in the Y-axis direction on the basis of the information relating to the spacing acquired using the second measurement system 37. In addition, the control unit 8 controls the position of the second mobile unit 34 in the X-axis direction on the basis of the measurement result of the first measurement system 36. Furthermore, the control unit 8 controls the position of the first mobile unit 32 in the Y-axis direction on the basis of the measurement result of the third measurement system 38. In addition, the control unit 8 may control the position of the first mobile unit 32 or the second mobile unit 34 by using the results of any of the first to third measurement systems 36, 37, and 38 in combination. For example, the control unit 8 may control the position of the second mobile unit 34 in the Y-axis direction on the basis of the measurement result of the second measurement system 37 and the measurement result of the third measurement system 38. For example, the control unit 8 may control the positions of the second mobile unit 34 in the X-axis direction and the Y-axis direction on the basis of the measurement results of the first measurement system 36, the second measurement system 37, and the third measurement system 38. Furthermore, the control unit 8 controls the movement of the first mobile unit 32 on the basis of correction information of grating lines constituting the X encoder scale 41. In this way, the control unit 8 obtains positional information of the second mobile unit 34 (strictly speaking, the exposure target object P placed on the second mobile unit 34) in the XY plane with reference to the optical surface plate 5 on the basis of each piece of the acquired information described above and performs position control of the exposure target object P with respect to the projection module 17 using a stage drive system that is not shown.

As shown in FIG. 7, the exposure apparatus 1 further has a stopper 39. The stopper 39 is attached to the first mobile unit 32. The stopper 39 protrudes further in the +Y-axis direction than the X encoder scale 41 attached to the first mobile unit 32. In other words, a distance between the stopper 39 and the X encoder head 45 is smaller than a distance between the X encoder scale 41 and the X encoder head 45. By providing the stopper 39, when the first mobile unit 32 and the second mobile unit 34 approach each other in the Y-axis direction, the stopper 39 is brought into contact with the X encoder head 45 before the X encoder scale 41. Therefore, the stopper 39 physically (mechanically) suppresses contact between the X encoder scale 41 of the first mobile unit 32 and the X encoder head 45 of the second mobile unit 34.

In such an exposure apparatus 1, the exposure target object P is exposed with light from the illumination optical apparatus 6 while moving the second mobile unit 34 holding the exposure target object P in the X-axis direction. More specifically, at the time of performing an exposure operation, after a first shot region of the exposure target object P (substrate) is exposed with light from the illumination optical apparatus 6, the second mobile unit 34 holding the exposure target object P is moved in the Y-axis direction. Thereafter, a second shot region lined up with the first shot region in the Y-axis direction on the exposure target object P is exposed with light from the illumination optical apparatus 6. A movable range of the second mobile unit 34 in the Y-axis direction (a movable range in a step direction) is smaller than a movable range of the second mobile unit 34 in the X-axis direction (a movable range in the scanning direction). As described above, when the second mobile unit 34 is moved in steps in the Y-axis direction, the first mobile unit 32 is moved by the same movement amount as the movement amount of the second mobile unit 34. Therefore, during the exposure operation, the X encoder scale 41 of the first mobile unit 32 and the X encoder head 45 of the second mobile unit 34 are arranged such that their positional relation with each other is invariable in the Y-axis direction.

In addition, positional information of the second mobile unit 34 (the exposure target object P) in each of the Z-axis, θx, and θy directions (hereinafter referred to as “Z tilt directions”) may be obtained by the control unit 8 using a Z tilt position measurement system, which is not shown, provided in the exposure apparatus 1. As the Z tilt position measurement system, for example, a measurement system using a displacement sensor attached to the second mobile unit 34 can be used.

According to the exposure apparatus 1 of the present embodiment described above, since the position of the second mobile unit 34 (exposure target object P) in the X-axis direction is measured using the first measurement system 36 including the linear encoder system, the influence of air fluctuation is small, and the position of the exposure target object P can be controlled with high precision compared with measurement using a conventional optical interferometer system. As a result, the exposure accuracy can be improved.

In addition, information relating to a spacing in the Y-axis direction between the first mobile unit 32 and the second mobile unit 34 can be acquired using the second measurement system 37 including the optical interferometer system. Since the reflection surface 32a of the second measurement system 37 and the X encoder scale 41 of the first measurement system 36 are provided on the same surface of the first mobile unit 32 (a moving mirror), an increase in the number of parts and complexity of the apparatus can be suppressed even in a case in which a plurality of measurement systems are arranged.

Since a plurality of X encoder heads 45 are provided to be aligned in the X-axis direction, for example, even in a case in which elongation due to thermal deformation occurs in the X encoder scale 41, an error due to the elongation can be corrected. In other words, by using the measurement values of a pair of X encoder heads 45 of which a separation distance from each other is known, the absolute value of the position of the second mobile unit 34 in the X-axis direction can be calculated (estimated), and thus, in a case in which elongation occurs in the X encoder scale 41, the position of the exposure target object P can be controlled with higher precision by correcting the error.

Since the first measurement system 36 and the second measurement system 37 measure the position of the exposure target object P with respect to the optical surface plate 5 indirectly or directly, the position measurement of the exposure target object P can be performed substantially with reference to the projection module 17 of the illumination optical apparatus 6. In accordance with this, since the position control of the exposure target object P can be performed with reference to the illumination light of the illumination optical apparatus 6, the exposure accuracy can be improved.

The configuration of the exposure apparatus 1 and the stage moving device 7 described above can be implemented by executing a method for driving a mobile unit using the exposure apparatus 1 and the stage moving device 7 described above (that is, a method for driving a mobile unit). In other words, the configuration of the exposure apparatus 1 and the stage moving device 7 of the present embodiment can be paraphrased as follows. In other words, a method for driving a mobile unit is a method for driving a mobile unit that moves a first mobile unit 32 extending in a first direction (the X-axis direction in the present embodiment) and moving in a second direction (the Y-axis direction in the present embodiment) intersecting the X-axis direction and a second mobile unit 34 moving in the Y-axis direction, the method including: measuring a position of the second mobile unit 34 in the X-axis direction by using a first head (the X encoder head 45 in the present embodiment) provided on one of the first mobile unit 32 and the second mobile unit 34 and a scale (the X encoder scale 41 in the present embodiment) extending in the X-axis direction and provided on the other of the first mobile unit 32 and the second mobile unit 34 so as to face the X encoder head 45; acquiring information relating to a spacing between the first mobile unit 32 and the second mobile unit 34; and driving the first mobile unit 32 and the second mobile unit 34 on the basis of a measurement result relating to the second mobile unit 34 and the information relating to the spacing.

Alternatively, it can be paraphrased as follows. In other words, a method for driving a mobile unit is a method for driving a mobile unit that moves a first mobile unit 32 extending in a first direction (the X-axis direction in the present embodiment) and moving in a second direction (the Y-axis direction in the present embodiment) intersecting the X-axis direction and a second mobile unit 34 moving in the Y-axis direction, the method including: measuring a position of the second mobile unit 34 in the X-axis direction by using a first head (the X encoder head 45 in the present embodiment) provided on one of the first mobile unit 32 and the second mobile unit 34 and a scale (the X encoder scale 41 in the present embodiment) extending in the X-axis direction and provided on the other of the first mobile unit 32 and the second mobile unit 34 so as to face the X encoder head 45; acquiring information relating to a positional relation between the first mobile unit 32 and the second mobile unit 34 in the Y-axis direction; measuring a position of the first mobile unit 32 in the Y-axis direction; and controlling a position of the second mobile unit 34 in the X-axis direction and the Y-axis direction on the basis of the measured position of the second mobile unit 34 in the X-axis direction, the acquired information relating to the positional relation between the first mobile unit 32 and the second mobile unit 34, and the measured position of the first mobile unit 32 in the Y-axis direction.

Alternatively, the configuration of the exposure apparatus 1 and the stage moving device 7 described above can be implemented by executing a method of exposing an exposure target object P using the exposure apparatus 1 and the stage moving device 7 described above (that is, an exposure method). In other words, the configuration of the exposure apparatus 1 and the stage moving device 7 of the present embodiment can be paraphrased as follows. In other words, an exposure method is an exposure method for exposing an exposure target object P using an exposure apparatus 1 including: a first mobile unit 32 extending in a first direction (the X-axis direction in the present embodiment) and moving in a second direction (the Y-axis direction in the present embodiment) intersecting the X-axis direction; a second mobile unit 34 moving in the Y-axis direction; an object held by the second mobile unit 34 (the exposure target object P); and an optical system that emits light to the exposure target object P, the exposure method including: measuring a position of the second mobile unit 34 in the X-axis direction by using a first head (the X encoder head 45 in the present embodiment) provided on one of the first mobile unit 32 and the second mobile unit 34 and a scale (the X encoder scale 41 in the present embodiment) extending in the X-axis direction and provided on the other of the first mobile unit 32 and the second mobile unit 34 so as to face the X encoder head 45; acquiring information relating to a spacing between the first mobile unit 32 and the second mobile unit 34; controlling movements of the first mobile unit 32 and the second mobile unit 34 on the basis of a measurement result relating to the second mobile unit 34 and the information relating to the spacing; and exposing the exposure target object P with light from the illumination optical apparatus 6 while moving the second mobile unit 34 holding the exposure target object P in the X-axis direction.

Alternatively, the configuration of the exposure apparatus 1 and the stage moving device 7 described above can be implemented by executing a method for manufacturing a device using the exposure apparatus 1 and the stage moving device 7 described above (that is, a device manufacturing method). In other words, the configuration of the exposure apparatus 1 and the stage moving device 7 of the present embodiment can be paraphrased as follows. In other words, a device manufacturing method is a device manufacturing method for manufacturing a substrate P for a device using the exposure apparatus 1 described above, the method including: exposing the substrate P; and developing the exposed substrate P.

Next, second to sixth embodiments of the present invention will be respectively described. In the following description, the same reference numerals are given to configurations similar to those of the above-described first embodiment, and description thereof will be omitted as appropriate. In addition, a specific configuration is not limited to these embodiments and can be changed as appropriate without departing from the gist of the present invention.

### Second Embodiment

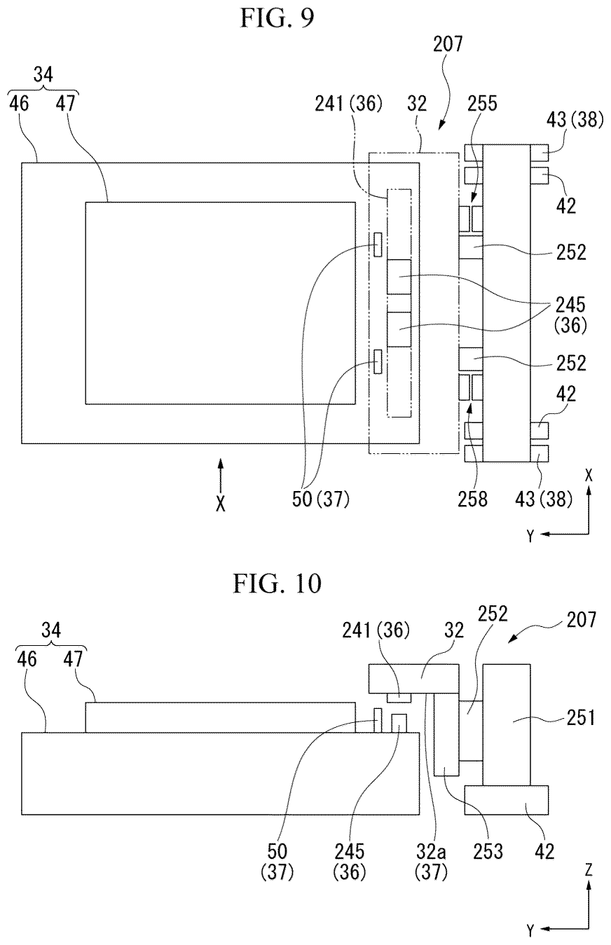

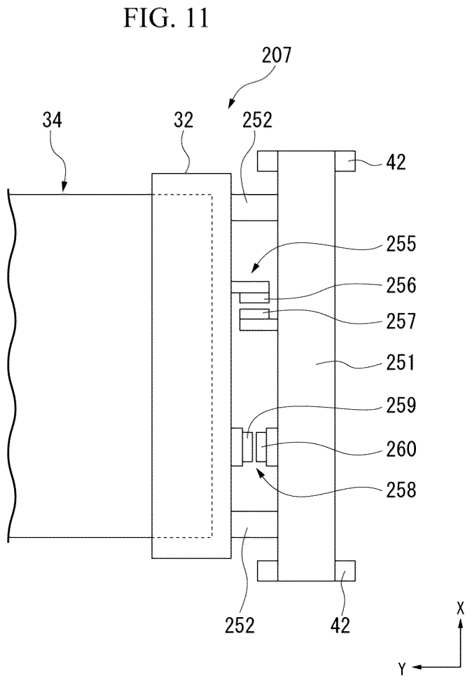

First, the second embodiment of the present invention will be described with reference to FIGS. 9 to 11. FIG. 9 is a plan view schematically showing a configuration of a stage moving device 207 according to the second embodiment. FIG. 10 is a front view schematically showing the configuration of the stage moving device 207 according to the second embodiment. FIG. 10 is a view taken in the direction of an arrow X in FIG. 9. FIG. 11 is a plan view schematically showing a configuration of a plurality of encoder measurement systems 255 and 258 of the stage moving device 207 according to the second embodiment. The second embodiment is different from the above-described first embodiment in that a first mobile unit 32 is configured to be movable also in a Z-axis direction, and a facing direction of a first measurement system 36 is the Z-axis direction.

In the second embodiment, the first mobile unit 32 of the stage moving device 207 is provided to be movable in biaxial directions including a Y-axis direction and a Z-axis direction with respect to a base member 30 (see FIG. 2). More specifically, the first mobile unit 32 is attached to the base member 30 through a Y guide 42, a Y stage 251, a Z guide 252, and a Z stage 253. Since the Y guide 42 has a configuration equivalent to that of the Y guide 42 of the first embodiment, description thereof will be omitted. The Y stage 251 is movably connected to the Y guide 42. By driving the Y guide 42, the Y stage 251 is movable in the Y-axis direction. A pair of Z guides 252 are attached onto the Y stage 251. The pair of Z guides 252 are arranged in parallel at a predetermined spacing in an X-axis direction. The pair of Z guides 252 include a linear guide mechanism and a drive motor that are not shown. The Z stage 253 is movably connected to the Z guides 252. By driving the Z guides 252, the Z stage 253 is movable in the Z-axis direction. The first mobile unit 32 is fixed to the Z stage 253.

As shown in FIG. 11, a first encoder measurement system 255 and a second encoder measurement system 258 are provided between the first mobile unit 32 and the base member 30. The first encoder measurement system 255 has, for example, an encoder scale 256 attached to the first mobile unit 32 (a moving mirror) and extending in the Z-axis direction and an encoder head 257 attached to the base member 30 and facing the encoder scale 256. The encoder scale 256 has a reflective 1.5-dimensional diffraction grating in which the Z-axis direction, which is a major axis direction, and the Y-axis direction, which is a minor axis direction, are set as periodic directions. By using the first encoder measurement system 255, position information of the first mobile unit 32 with respect to the base member 30 in the Z-axis direction, the Y-axis direction, and the θx direction can be measured. The second encoder measurement system 258 has, for example, an encoder scale 259 attached to the first mobile unit 32 (moving mirror) and extending in the Z-axis direction and an encoder head 260 attached to the base member 30 and facing the encoder scale 259. The encoder scale 259 has a reflective 1.5-dimensional diffraction grating in which the Z-axis direction, which is a major axis direction, and the X-axis direction, which is a minor axis direction, are set as periodic directions. By using the second encoder measurement system 258, position information of the first mobile unit 32 with respect to the base member 30 in the Z-axis direction, the X-axis direction, and the θy direction can be measured.

As shown in FIGS. 9 and 10, the first mobile unit 32 has a reflection surface 32a formed at least on a lower surface (a surface facing a −Z-axis direction). An X encoder scale 241 extending along the X-axis direction is provided on the lower surface of the first mobile unit 32. The X encoder scale 241 of the second embodiment has a reflective 1.5-dimensional diffraction grating in which the X-axis direction, which is a major axis direction, and the Y-axis direction, which is a minor axis direction, are set as periodic directions. Furthermore, a pair of XY encoder heads 245 are provided on a second mobile unit 34 so as to face the X encoder scale 241. The XY encoder heads 245 are provided below the X encoder scale 241 (in the −Z-axis direction) and face the X encoder scale 241 in the Z-axis direction. The first measurement system 36 has this X encoder scale 241 and the XY encoder heads 245. By using the first measurement system 36, positions of the second mobile unit 34 with respect to the first mobile unit 32 in the X-axis direction, the Y-axis direction, and the θz direction are measured.

An interferometer head 50 is provided on the second mobile unit 34. A plurality (two in the present embodiment) of interferometer heads 50 are provided to be aligned in the X-axis direction. A pair of interferometer heads 50 face the reflection surface 32a, which is provided on the lower surface of the first mobile unit 32 in the Z-axis direction, in the Z-axis direction. A distance between the interferometer heads 50 and the reflection surface 32a may be larger than a distance between the XY encoder heads 245 and the X encoder scale 241. A second measurement system 37 has these interferometer heads 50 and the reflection surface 32a. By using the second measurement system 37, positions of the second mobile unit 34 with respect to the first mobile unit 32 in the Z-axis direction and the θy direction are measured. In other words, the second measurement system 37 acquires information relating to a spacing in the Z-axis direction between the first mobile unit 32 and the second mobile unit 34.

In the exposure apparatus formed in this manner, the control unit 8 (see FIG. 1), similarly to the first embodiment, causes the first mobile unit 32 to step-move in the Y-axis direction following the step movement of the second mobile unit 34, on which an exposure target object P is placed, in the Y-axis direction. In accordance with this, control is performed such that a distance along the Y-axis direction between the first mobile unit 32 and the second mobile unit 34 becomes constant. Furthermore, in the second embodiment, the control unit 8 controls the position of the Z stage 253 in the Z direction on the basis of a measurement result acquired by the second measurement system 37 such that a distance along the Z-axis direction between the first mobile unit 32 and the second mobile unit 34 becomes constant.

According to the stage moving device 207 of the second embodiment, since the X encoder scale 241 having the 1.5-dimensional diffraction grating is used, position information (a minute change amount) in the θz direction and the Y-axis direction can be measured in addition to the position information in the X-axis direction by using one X encoder scale 241. Therefore, it is not necessary to provide a displacement sensor or the like for measuring the position information in the Y-axis direction between the first mobile unit 32 and the second mobile unit 34, and the number of parts can be reduced.

Since the stage moving device 207 has the first encoder measurement system 255 and the second encoder measurement system 258, a skew running error relating to the X-axis direction and the Y-axis direction at the time of driving the first mobile unit 32 in the Z-axis direction can be monitored.

In addition, in the present embodiment, a Z-tilt position measurement system (not shown) for measuring position information of the second mobile unit 34 with respect to the first mobile unit 32 in the θx direction may be separately provided. As the Z-tilt position measurement system, for example, a measurement system using a displacement sensor, which is not shown, attached to the second mobile unit 34 or the like can be used.

### Third Embodiment

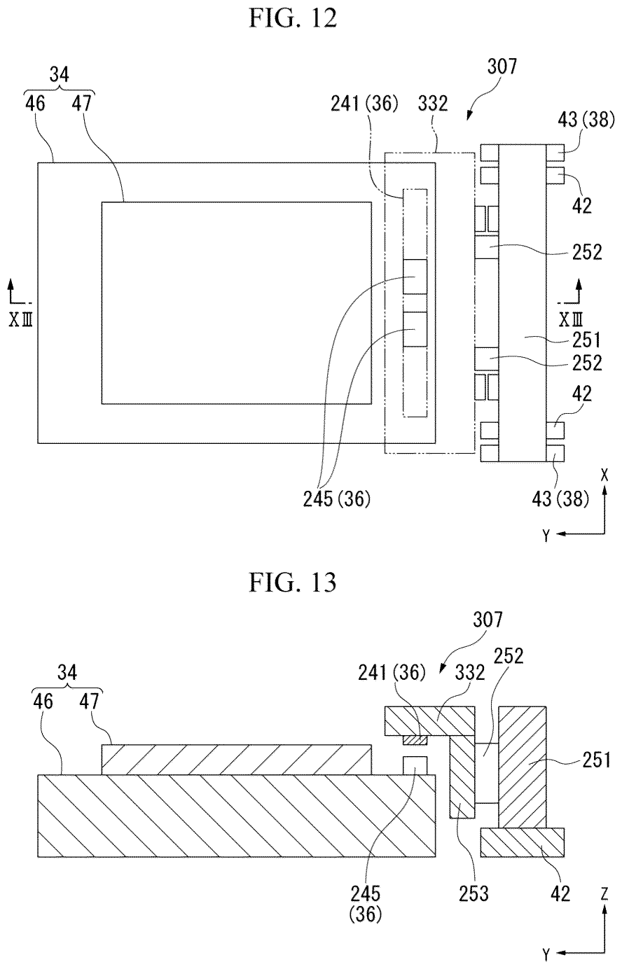

Next, a third embodiment of the present invention will be described with reference to FIGS. 12 and 13. FIG. 12 is a plan view schematically showing a configuration of a stage moving device 307 according to the third embodiment. FIG. 13 is a front view schematically showing the configuration of the stage moving device 307 according to the third embodiment. FIG. 13 is a cross-sectional view taken along line XIII-XIII in FIG. 12. The third embodiment is different from each of the embodiments described above in that a member other than the moving mirror is used as a first mobile unit 332. Since the configuration of the stage moving device 307 of the third embodiment is substantially the same as that of the second embodiment except that the first mobile unit 332 is not a moving mirror (does not have the reflection surface 32a), and the interferometer head 50 is not provided, hereinafter, only differences will be described, and description of the elements having the same configuration or function as those of the second embodiment will be omitted.

In the third embodiment, the first mobile unit 332 of the stage moving device 307 is a rod-shaped member extending in the X-axis direction and formed in a rectangular shape in the YZ cross section. The first mobile unit 332 is formed without having the reflection surface 32a (see FIG. 10) on the surface thereof. A 1.5-dimensional X encoder scale 241 extending along the X-axis direction is provided on a lower surface (a surface facing the −Z-axis direction) of the first mobile unit 332. A pair of XY encoder heads 245 are provided on the second mobile unit 34 so as to face the X encoder scale 241. In addition, in order to measure a position of the second mobile unit 34 in the Z-axis direction, a sensor or the like (not shown) capable of measuring a height position of the second mobile unit in the Z-axis direction with respect to an optical surface plate 5 may be separately provided.

According to the stage moving device 307 of the third embodiment, by employing a configuration without a moving mirror for the first mobile unit 332, the configuration of the stage moving device 307 can be simplified, and costs relating to manufacturing of the first mobile unit 332 can be reduced. In addition, the versatility of the stage moving device 307 can be improved. Furthermore, by using the 1.5-dimensional X encoder scale 241 and the XY encoder heads 245, even in a case in which the moving mirror is not used, the positions of the second mobile unit 34 with respect to the first mobile unit 332 in the X-axis direction and the Y-axis direction can be measured.

### Fourth Embodiment

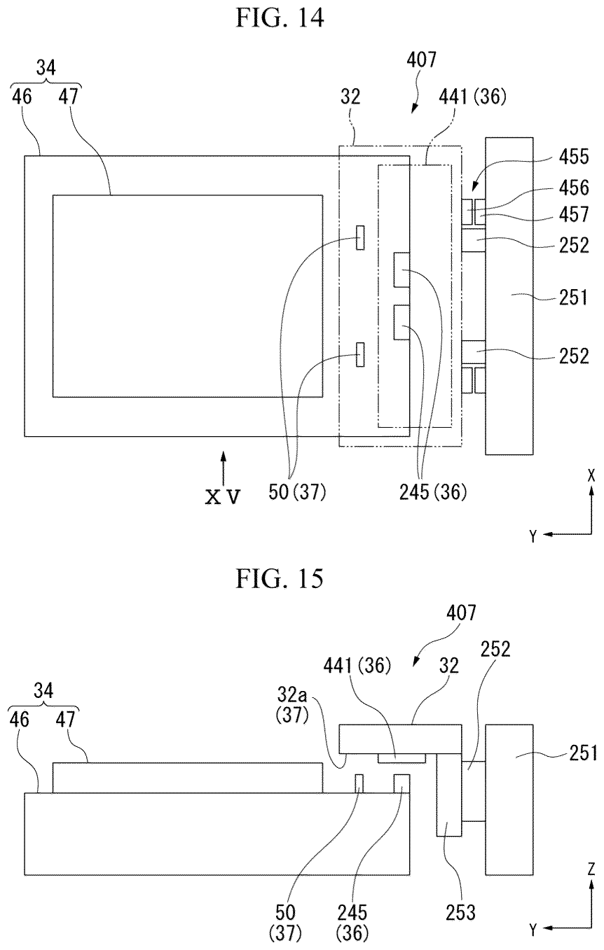

Next, a fourth embodiment of the present invention will be described with reference to FIGS. 14 and 15. FIG. 14 is a plan view schematically showing a configuration of a stage moving device 407 according to the fourth embodiment. FIG. 15 is a front view schematically showing the configuration of the stage moving device 407 according to the fourth embodiment. FIG. 15 is a view taken in the direction of arrow XV in FIG. 14. The fourth embodiment is different from each of the above-described embodiments in that a two-dimensional encoder scale 441 is attached to a first mobile unit 32. Since the configuration of the stage moving device 407 of the fourth embodiment is substantially the same as that of the above-described second embodiment except that the encoder scale 441 is two-dimensional, and an encoder measurement system 455 of the first mobile unit 32 is provided only in the Z-axis direction, hereinafter, only differences will be described, and description of elements having the same configuration or function as those of the second embodiment will be omitted.

In the fourth embodiment, the first mobile unit 32 of the stage moving device 407 is a moving mirror, and a reflection surface 32a is formed on a lower surface (a surface facing the −Z-axis direction) of the first mobile unit 32. An encoder scale 441 parallel to the XY plane is provided on the lower surface of the first mobile unit 32. The encoder scale 441 may be formed such that a length dimension along the X-axis direction is larger than a length dimension along the Y-axis direction. The encoder scale 441 has a reflective two-dimensional diffraction grating in which the X-axis direction and the Y-axis direction are set as periodic directions. A first measurement system 36 includes this encoder scale 441 and an encoder head 245 provided on the second mobile unit 34. The first measurement system 36 measures positions of the second mobile unit 34 with respect to the first mobile unit 32 in the X-axis direction, the Y-axis direction, and the θz direction.

In addition, the stage moving device 407 has a reflection surface 32a and a pair of interferometer heads 50 provided on the second mobile unit 34 so as to face the reflection surface 32a as the second measurement system 37. By using the second measurement system 37, positions of the second mobile unit 34 with respect to the first mobile unit 32 in the Z-axis direction and the θy direction are measured.

In the stage moving device 407 of the present embodiment, the control unit 8 (see FIG. 1) causes the first mobile unit 32 to step-move in the Z-axis direction following movement of the second mobile unit 34, on which an exposure target object P is placed, in the Z-axis direction. Regarding movement of the second mobile unit 34 in the X-axis direction and the Y-axis direction, the first mobile unit 32 does not follow. In other words, positions of the first mobile unit 32 in the X-axis direction and the Y-axis direction are fixed. In this case, the first mobile unit 32 may be formed without having the Y guide 42 (see FIG. 10) according to the second embodiment.

In addition, an encoder measurement system 455 is provided between the first mobile unit 32 and the base member 30. The encoder measurement system 455 has, for example, an encoder scale 456 attached to the first mobile unit 32 and extending in the Z-axis direction and an encoder head 457 attached to the base member 30 and facing the encoder scale 456. The encoder scale 456 has a reflective 1.5-dimensional diffraction grating in which the Z-axis direction, which is a major axis direction, and the X-axis direction, which is a minor axis direction, are set as periodic directions. By using the encoder measurement system 455, position information of the first mobile unit 32 with respect to the base member 30 in the Z-axis direction, the X-axis direction, and the θy direction can be measured.

According to the stage moving device 407 of the fourth embodiment, by using the two-dimensional encoder scale 441, the positions of the second mobile unit 34 with respect to the first mobile unit 32 in the X-axis direction, the Y-axis direction, and the θz direction can be measured. Therefore, the configuration of the stage moving device 407 can be simplified. In addition, the versatility of the stage moving device 407 can be improved. In particular, it can be suitably used as a stage moving device for direct drawing with a small driving amount in the Y-axis direction.

### Fifth Embodiment

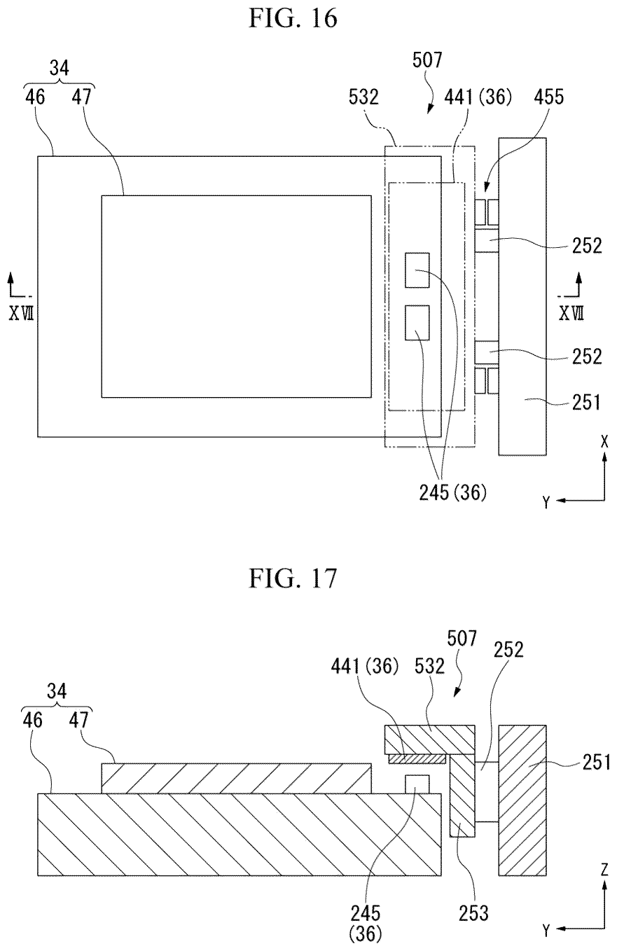

Next, a fifth embodiment of the present invention will be described with reference to FIGS. 16 and 17. FIG. 16 is a plan view schematically showing a configuration of a stage moving device 507 according to the fifth embodiment. FIG. 17 is a front view schematically showing the configuration of the stage moving device 507 according to the fifth embodiment. FIG. 17 is a cross-sectional view taken along line XVII-XVII in FIG. 16. The fifth embodiment is different from the above-described fourth embodiment in that the first mobile unit 32 according to the fourth embodiment is formed without a moving mirror. Since the configuration of the stage moving device 507 of the fifth embodiment is substantially the same as that of the above-described fourth embodiment except that a first mobile unit 532 is not a moving mirror (does not have the reflection surface 32a), and the interferometer head 50 is not provided, hereinafter, only differences will be described, and description of elements having the same configuration or function as those of the fourth embodiment will be omitted.

In the fifth embodiment, the first mobile unit 532 of the stage moving device 507 is a rod-shaped member extending in the X-axis direction and formed in a rectangular shape in the YZ cross section. The first mobile unit 532 is formed without having the reflection surface 32a (see FIG. 15) on the surface thereof. An encoder scale 441 parallel to the XY plane is provided on a lower surface (a surface facing the-Z-axis direction) of the first mobile unit 532. A pair of encoder heads 245 are provided on the second mobile unit 34 so as to face the encoder scale 441. In addition, in order to measure the position of the second mobile unit 34 in the Z-axis direction, a sensor or the like (not shown) capable of measuring a height position of the second mobile unit in the Z-axis direction with respect to the optical surface plate 5 may be separately provided.

According to the stage moving device 507 of the fifth embodiment, by employing a configuration without a moving mirror for the first mobile unit 532, the configuration of the stage moving device 507 can be simplified and costs relating to manufacturing of the first mobile unit 532 can be reduced as compared to the configuration of the fourth embodiment. In addition, the versatility of the stage moving device 507 can be improved. Furthermore, by using the two-dimensional encoder scale 441, even in a case in which the moving mirror is not used, the positions of the second mobile unit 34 with respect to the first mobile unit 532 in the X-axis direction, the Y-axis direction, and the θz direction can be measured.

### Sixth Embodiment

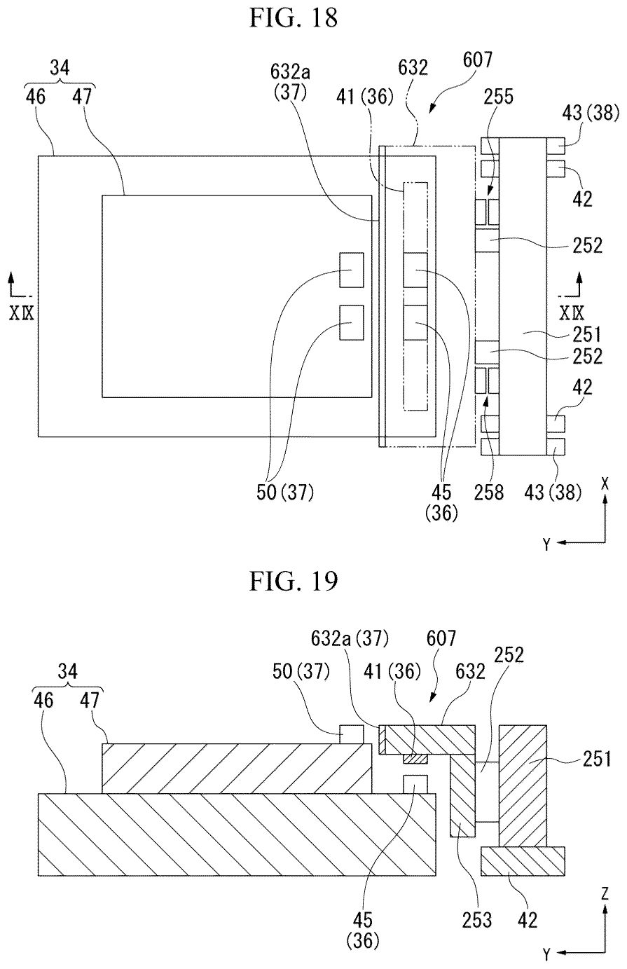

Next, a sixth embodiment of the present invention will be described with reference to FIGS. 18 and 19. FIG. 18 is a plan view schematically showing a configuration of a stage moving device 607 according to the sixth embodiment. FIG. 19 is a front view schematically showing the configuration of the stage moving device 607 according to the sixth embodiment. FIG. 19 is a cross-sectional view taken along line XIX-XIX in FIG. 18. The sixth embodiment is different from each of the embodiments described above in that an X encoder scale 41 used for a first measurement system 36 and a reflection surface 632a used for the second measurement system 37 are provided on different surfaces on a first mobile unit 632.

In the sixth embodiment, the first mobile unit 632 of the stage moving device 607 is movably provided with respect to the base member 30 through a Y guide 42, a Y stage 251, a Z guide 252, and a Z stage 253. In addition, a first encoder measurement system 255 and a second encoder measurement system 258 are provided between the first mobile unit 632 and the base member 30. The configurations of the Y guide 42, the Y stage 251, the Z guide 252, the Z stage 253, the first encoder measurement system 255, and the second encoder measurement system 258 are equivalent to those according to the second embodiment, and thus descriptions thereof are omitted here.

The first mobile unit 632 is a rod-shaped member extending in the X-axis direction and formed in a rectangular shape in the YZ cross section. A one-dimensional X encoder scale 41 extending along the X-axis direction is provided on a lower surface (a surface facing the −Z-axis direction) of the first mobile unit 632. A pair of X encoder heads 45 are provided on the second mobile unit 34 so as to face the X encoder scale 41. The first measurement system 36 includes this X encoder scale 41 and the X encoder heads 45. By using the first measurement system 36, a position of the second mobile unit 34 with respect to the first mobile unit 32 in the X-axis direction is measured.

The reflection surface 632a is formed on a surface of the first mobile unit 632 facing the +Y-axis direction. The reflection surface 632a is provided on the rod-shaped member, for example, by adhering a member having a mirror surface to a rod-shaped member. In addition, the reflection surface 632a may be formed integrally with a rod-shaped member by applying metal deposition or the like to the rod-shaped member. The rod-shaped member (that is, the first mobile unit 32) may have the reflection surface 632a at least on a surface facing the +Y-axis direction, and, for example, reflection surfaces 632a may be provided on a plurality of surfaces of the rod-shaped member. A pair of interferometer heads 50 are provided on the second mobile unit 34 so as to face the reflection surface 632a. The pair of interferometer heads 50, for example, are attached to a plate holder 47 of the second mobile unit 34 and face the reflection surface 632a in the Y-axis direction. The second measurement system 37 includes these interferometer heads 50 and the reflection surface 632a. By using the second measurement system 37, positions of the second mobile unit 34 with respect to the first mobile unit 32 in the Y-axis direction and the θz direction are measured.

In the exposure apparatus 1 formed in this way, the control unit 8 (see FIG. 1) causes the first mobile unit 632 to step-move in the Y-axis direction following the step movement of the second mobile unit 34, on which the exposure target object P is placed, in the Y-axis direction. In accordance with this, control is performed such that a distance along the Y-axis direction between the first mobile unit 632 and the second mobile unit 34 becomes constant. In addition, in the present embodiment, in order to measure the positions of the first mobile unit 632 and the second mobile unit 34 in the Z-axis direction, sensors or the like (not shown) capable of measuring height positions of the first mobile unit 632 and the second mobile unit 34 in the Z-axis direction with respect to the optical surface plate 5 may be separately provided. In this case, the control unit 8 may control the position of the Z stage 253 in the Z direction on the basis of an output result of the sensor measuring the height position in the Z-axis direction and a measurement result of the second measurement system 37 such that a distance along the Z-axis direction between the first mobile unit 632 and the second mobile unit 34 becomes constant.

According to the stage moving device 607 of the sixth embodiment, the X encoder scale 41 and the reflection surface 632a are provided on mutually different surfaces of the first mobile unit 632, and thus a degree of freedom in designing the first mobile unit 632 can be increased. As a result, the versatility of the stage moving device 607 can be improved.

The technical scope of the present invention is not limited to the above-described embodiments, and various modifications can be added without departing from the gist of the present invention.

For example, in the above-described first embodiment, although the configuration in which the first measurement system 36 has the X encoder scale 41 provided on the first mobile unit 32 and the X encoder heads 45 provided on the second mobile unit 34 has been described, the configuration is not limited to this. The X encoder head 45 may be provided on the first mobile unit 32, and the X encoder scale 41 may be provided on the second mobile unit 34. In other words, the first measurement system 36 may measure the position of the second mobile unit 34 by using the X encoder head 45 provided on one of the first mobile unit 32 and the second mobile unit 34 and the X encoder scale 41 extending in the X-axis direction and provided on the other of the first mobile unit 32 and the second mobile unit 34 so as to face the X encoder head 45. Similarly, regarding the second measurement system 37, the interferometer head 50 may be provided on the first mobile unit 32, and the reflection surface 32a may be provided on the second mobile unit 34. In other words, the second measurement system 37 may acquire information relating to the spacing between the first mobile unit 32 and the second mobile unit 34 by using the reflection surface 32a provided on one of the first mobile unit 32 and the second mobile unit 34 and at least one interferometer head 50 provided on the other of the first mobile unit 32 and the second mobile unit 34. Similarly, regarding the third measurement system 38, the Y encoder head 44 may be provided on the base member 30, and the Y encoder scale 43 may be provided on the first mobile unit 32. In other words, the third measurement system 38 may measure the position of the first mobile unit 32 by using the Y encoder scale 43 provided on one of the first mobile unit 32 and the base member 30 and at least one Y encoder head 44 provided on the other of the first mobile unit 32 and the base member 30.

The third measurement system 38 may be configured as an optical interferometer system having a second reflection surface (not shown) and a second interferometer head (not shown) facing the second reflection surface instead of the Y encoder scale 43 and the Y encoder heads 44.

The plate holder 47 of the second mobile unit 34 may be a type of holder that adsorbs and holds an exposure target object P.

The first measurement system 36, the second measurement system 37, and the third measurement system 38 may obtain position information of the first mobile unit 32 and the second mobile unit 34 with reference to the optical surface plate 5. The exposure apparatus 1 may have a plurality of measurement systems in addition to the first measurement system 36, the second measurement system 37, and the third measurement system 38 described above.

An encoder head (for example, the X encoder head 45 or the XY encoder head 245) used in the measurement system of a linear encoder system does not need to have an entire optical system for emitting a beam from a light source to the encoder scale and may have only a part of the optical system, for example, only an emission unit.

As for applications of the exposure apparatus 1, it can be widely applied to an exposure apparatus for liquid crystal that transfers a liquid-crystal display element pattern onto a rectangular glass plate, an exposure apparatus for manufacturing an organic electro-luminescence (EL) panel, an exposure apparatus for manufacturing a semiconductor, an exposure apparatus for manufacturing a thin film magnetic head, a micromachine, a DNA chip, and the like. An object to be an exposure target object is not limited to a glass substrate and may be another object such as a wafer, a ceramic substrate, a film member, or a mask blank. Furthermore, in a case in which the exposure target object is a substrate for a flat-panel display, the thickness of the substrate is not particularly limited, and it also includes a film-like substrate (a flexible sheet-like member).

A plurality of components of the respective embodiments described above can be combined as appropriate. In addition, some of the plurality of components described above may not be used.

### REFERENCE SIGNS LIST

1 Exposure apparatus
6 Illumination optical apparatus (optical system)
7, 207, 307, 407, 507, 607 Stage moving device (moving device)
17 Projection module (projection optical system)
30 Base member
32, 332, 532, 632 First mobile unit
32a, 632a Reflection surface (first measurement member)
34 Second mobile unit
36 First measurement system
37 Second measurement system
38 Third measurement system
39 Stopper
41, 241 X encoder scale (scale)
43 Y encoder scale (second measurement member)
44 Y encoder head (third head)
45 X encoder head (first head)
46 Plate table (table)
50 Interferometer head (second head)
245 XY encoder head (first head)
441 Encoder scale (scale)
P Exposure target object (object, substrate)

What is claimed is:

1. A moving device comprising:
a first mobile unit extending in a first direction and moving in a second direction intersecting the first direction;
a second mobile unit moving in the second direction;
a first measurement system measuring a position of the second mobile unit in the first direction by using a first head provided on one of the first mobile unit and the second mobile unit and a scale extending in the first direction and provided on the other of the first mobile unit and the second mobile unit so as to face the first head; and
a second measurement system acquiring information relating to a spacing between the first mobile unit and the second mobile unit.

2. The moving device according to claim 1, wherein the spacing is controlled on the basis of a measurement result acquired by the second measurement system.

3. The moving device according to claim 1, wherein the first mobile unit moves in the second direction in connection with movement of the second mobile unit in the second direction.

4. The moving device according to claim 1,
wherein the first head is provided on the second mobile unit, and
wherein the scale is provided on the first mobile unit.

5. The moving device according to claim 1,
wherein the second mobile unit is movable in the first direction, and
wherein a position of the second mobile unit in the first direction is controlled on the basis of a measurement result acquired by the first measurement system.

6. The moving device according to claim 1, wherein the first measurement system includes a plurality of the first heads provided on a table having a smaller coefficient of thermal expansion than the scale and aligned in the first direction.

7. The moving device according to claim 1, further comprising a stopper,
wherein a distance between the stopper and the first head is smaller than a distance between the scale and the first head.

8. The moving device according to claim 1, wherein the second measurement system includes an interferometer system.

9. The moving device according to claim 1, wherein the second measurement system acquires the information relating to the spacing at a plurality of positions in the first direction.

10. The moving device according to claim 1, wherein the second measurement system acquires the information relating to the spacing by using a first measurement member provided on one of the first mobile unit and the second mobile unit and at least one second head provided on the other of the first mobile unit and the second mobile unit.

11. The moving device according to claim 10, wherein the second measurement system acquires the information relating to the spacing by using the first measurement member provided on the first mobile unit and the at least one second head provided on the second mobile unit,
wherein the first measurement member and the scale are provided on the first mobile unit,
wherein the first head and the at least one second head are provided on the second mobile unit,
wherein the first measurement member and the scale are provided on the same side of the first mobile unit,
wherein the first head faces the scale in the second direction, and
wherein the at least one second head faces the first measurement member in the second direction.

12. The moving device according to claim 1,
wherein the second measurement system acquires the information relating to the spacing in the second direction, and
wherein a position of the second mobile unit in the second direction is controlled on the basis of the information relating to the spacing acquired using the second measurement system.

13. The moving device according to claim 1, wherein the second measurement system acquires the information relating to the spacing in a third direction intersecting the first direction and the second direction between the first mobile unit and the second mobile unit.

14. The moving device according to claim 13, wherein the first head faces the scale in the third direction.

15. The moving device according to claim 12, further comprising a third measurement system measuring a position of the first mobile unit in the second direction,
wherein the position of the second mobile unit in the second direction is controlled on the basis of a measurement result acquired by the second measurement system and a measurement result acquired by the third measurement system.

16. A moving device comprising:
a first mobile unit extending in a first direction and moving in a second direction intersecting the first direction;
a second mobile unit moving in the second direction;
a first measurement system measuring a position of the second mobile unit in the first direction by using a first head provided on one of the first mobile unit and the second mobile unit and a scale extending in the first direction and provided on the other of the first mobile unit and the second mobile unit so as to face the first head;
a second measurement system acquiring information relating to a positional relation between the first mobile unit and the second mobile unit in the second direction; and
a third measurement system measuring a position of the first mobile unit in the second direction,
wherein positions of the second mobile unit in the first direction and the second direction are controlled on the basis of measurement results acquired by the first measurement system, the second measurement system, and the third measurement system.

17. The moving device according to claim 1, further comprising a third measurement system measuring a position of the first mobile unit in the second direction.

18. The moving device according to claim 17, wherein the position of the first mobile unit in the second direction is controlled on the basis of a measurement result acquired by the third measurement system.

19. The moving device according to claim 15, further comprising a base member,
wherein the third measurement system measures the position of the first mobile unit in the second direction by using a third head provided on one of the first mobile unit and the base member and a second measurement member provided on the other of the first mobile unit and the base member so as to face the third head.

20. The moving device according to claim 1, wherein movement of the first mobile unit is controlled on the basis of correction information of grating lines constituting the scale.

21. An exposure apparatus comprising:
the moving device according to claim 19; and
an optical system supported by the base member,
wherein light from the optical system is emitted to an object held by the second mobile unit to expose the object,
wherein the object is exposed with the light from the optical system while the second mobile unit holding the object is moved in the first direction,
wherein, after a first shot region of the object is exposed with the light from the optical system, the second mobile unit holding the object is moved in the second direction, and thereafter, a second shot region lined up with the first shot region in the second direction on the object is exposed with the light from the optical system,
wherein the optical system includes a plurality of projection optical systems aligned in the second direction, and
wherein a movable range of the second mobile unit in the second direction is smaller than a movable range of the second mobile unit in the first direction.

22. A method for driving a mobile unit that moves a first mobile unit extending in a first direction and moving in a second direction intersecting the first direction and a second mobile unit moving in the second direction, the method comprising:
measuring a position of the second mobile unit in the first direction by using a first head provided on one of the first mobile unit and the second mobile unit and a scale extending in the first direction and provided on the other of the first mobile unit and the second mobile unit so as to face the first head;
acquiring information relating to a positional relation between the first mobile unit and the second mobile unit in the second direction;
measuring a position of the first mobile unit in the second direction; and
controlling positions of the second mobile unit in the first direction and the second direction on the basis of the measured position of the second mobile unit in the first direction, the acquired information, and the measured position of the first mobile unit in the second direction.

23. The method for driving a mobile unit according to claim 22, wherein the acquired information includes a spacing between the first mobile unit and the second mobile unit.

24. An exposure method of exposing an object using an exposure apparatus including a first mobile unit extending in a first direction and moving in a second direction intersecting the first direction, a second mobile unit moving in the second direction, the object held by the second mobile unit, and an optical system that emits light to the object, the method comprising:
the method for driving a mobile unit according to claim 23; and
exposing the object with the light from the optical system while moving, in the first direction, the second mobile unit holding the object.

25. A device manufacturing method comprising:
exposing a substrate using the exposure apparatus according to claim 21; and
developing the exposed substrate.
